(19) United States
(12) Patent Application Publication
(10) Pub. No.: US 2015/0047708 A1
(43) Pub. Date: Feb. 19, 2015

(54) ORGANIC-INORGANIC HYBRID PHOTOELECTRIC CONVERSION DEVICE

(71) Applicant: SUMITOMO CHEMICAL COMPANY, LIMITED, Chuo-ku, Tokyo (JP)

(72) Inventors: Yasunori Uetani, Tsukuba-shi (JP); Masahiko Hata, Tsukuba-shi (JP)

(73) Assignee: SUMITOMO CHEMICAL COMPANY, LIMITED, Chuo-ku, Tokyo (JP)

(21) Appl. No.: 14/385,692

(22) PCT Filed: Mar. 14, 2013
(86) PCT No.: PCT/JP2013/058190

§ 371 Date: Sep. 16, 2014

(30) Foreign Application Priority Data
Mar. 22, 2012 (JP) 2012-064928

(51) Int. Cl. H01L 51/42; H01L 51/00; H01L 27/30

(52) U.S. Cl. CPC H01L 51/4213; H01L 27/302; H01L 51/0002; H01L 2031/0344
USPC 136/261; 136/263; 438/82

(57) ABSTRACT

An organic-inorganic hybrid photoelectric conversion device comprising:
an inorganic photoelectric conversion device comprising an inorganic semiconductor; and
an organic photoelectric conversion device which is connected in series to the inorganic photoelectric conversion device and is superimposed on the inorganic photoelectric conversion device,
wherein the organic photoelectric conversion device comprises an active layer comprising an electron-accepting compound and an electron-donating compound and has an absorption edge at a wavelength shorter than that at which the inorganic photoelectric conversion device has. This photoelectric conversion device is capable of obtaining high open end voltage, and can be fabricated simply.

### TECHNICAL FIELD

The present invention relates to an organic-inorganic hybrid photoelectric conversion device.

### BACKGROUND ART

Inorganic photoelectric conversion devices using a semiconductor material such as silicon, CIGS, CdTe, GaAs or the like show an absorption edge at a relatively longer wavelength. Such inorganic photoelectric conversion devices can utilize lights in a wider wavelength range as electric power. For short wavelength lights showing high energy, however, the amount of energy which can be taken out outward as electric power is only a volume corresponding to the band gap and the residue is converted into heat and cannot be taken out outward as electric power.

As described above, when conventional inorganic photoelectric conversion devices are applied to short wavelength lights showing high energy, surplus energy is lost in the form of heat and sufficient electric power cannot be taken out.

In contrast, inorganic photoelectric conversion devices using a semiconductor material of small band gap showing an absorption edge at a longer wavelength can absorb also long wavelength lights showing low energy, thus, the number of electrons transferring from the valence band to the conduction band is large, resulting in increasability of electric current. When the band gap is small, however, voltage to be taken out is low, thus, even if electric current increases, sufficient electric power (=voltage×current) cannot be taken out.

Because of this situation, there is a report on a photoelectric conversion device having a structure called tandem obtained by laminating two or more inorganic photoelectric conversion devices containing semiconductors showing different band gaps as a constituent material (for example, Patent documents 1, 2). By adopting such a constitution, a photoelectric conversion device can effectively utilize also energy of short wavelength lights showing high energy.

### PRIOR ART DOCUMENTS

### Patent Documents

[Patent document 1] International Patent Publication WO 2001/024534
[Patent document 2] JP-A No. 6-283738

However, a photoelectric conversion device having a constitution containing laminated inorganic semiconductors is problematic in cost and productivity.

### SUMMARY OF THE INVENTION

### Problem to be Solved by the Invention

The present invention has an object of providing a photoelectric conversion device which can manifest high open end voltage and can be manufactured simply.

### Means for Solving the Problem

The present invention provides the following [1] to [7].

[1] An organic-inorganic hybrid photoelectric conversion device comprising:

an inorganic photoelectric conversion device comprising an inorganic semiconductor; and
an organic photoelectric conversion device which is connected in series to the inorganic photoelectric conversion device and is superimposed on the inorganic photoelectric conversion device,

wherein the organic photoelectric conversion device comprises an active layer comprising an electron-accepting compound and an electron-donating compound and has an absorption edge at a wavelength shorter than that at which the a inorganic photoelectric conversion device has.

[2] The organic-inorganic hybrid photoelectric conversion device according to [1], wherein the active layer of the above-described organic photoelectric conversion device has been formed by an application method.

[3] The organic-inorganic hybrid photoelectric conversion device according to [1] or [2], wherein an electrode of the organic photoelectric conversion device has been formed by an application method.

[4] The organic-inorganic hybrid photoelectric conversion device according to any one of [1] to [3], wherein the active layer of the organic photoelectric conversion device comprises a fullerene and/or a fullerene derivative and a conjugated polymer compound.

[5] The organic-inorganic hybrid photoelectric conversion device according to any one of [1] to [4], wherein the inorganic semiconductor used in the inorganic photoelectric conversion device is silicon.

[6] A method for producing an organic-inorganic hybrid photoelectric conversion device comprising:

a step of preparing an inorganic photoelectric conversion device; and
a step of forming an organic photoelectric conversion device on the inorganic photoelectric conversion device, wherein in the step of forming an organic photoelectric conversion device, an active layer of the organic photoelectric conversion device is formed by an application method on the inorganic photoelectric conversion device.

[7] The method for producing an organic-inorganic hybrid photoelectric conversion device according to [6], wherein in the step of forming the organic photoelectric conversion device, an electrode of the organic photoelectric conversion device is formed by an application method after the formation of an active layer.

### BRIEF EXPLANATION OF DRAWING

FIG. 1 is a view showing the spectral sensitivity of an organic photoelectric conversion device and an inorganic photoelectric conversion device.

### MODES FOR CARRYING OUT THE INVENTION

The present invention will be illustrated in detail below.

In the present specification, the absorption edge is defined as follows. That is, in a graph having the ordinate axis showing spectral sensitivity and the abscissa axis showing wavelength, a straight line is fitted to a portion wherein spectral sensitivity rises, and the value of a site where the straight line crosses the abscissa axis is defined as the absorption edge. The spectral sensitivity is measured by using a spectral sensitivity measuring apparatus.

### <1> Constitution of Photoelectric Conversion Device

The organic-inorganic hybrid photoelectric conversion device of the present invention is an organic-inorganic hybrid photoelectric conversion device comprising an inorganic photoelectric conversion device using an inorganic semiconductor and an organic photoelectric conversion device which is connected in series to the inorganic photoelectric conversion device and is arranged superimposed on the inorganic photoelectric conversion device, the above-described organic photoelectric conversion device being provided with an active layer that contains an electron-accepting compound and an electron-donating compound and showing an absorption edge at a shorter wavelength than that of the above-described inorganic photoelectric conversion device. The organic-inorganic hybrid photoelectric conversion device may be provided on a supporting substrate.

The organic photoelectric conversion device is fabricated, for example, directly on an inorganic photoelectric conversion device. Alternatively, it may be permissible that an organic photoelectric conversion device and an inorganic photoelectric conversion device are fabricated separately, then, the organic photoelectric conversion device is laminated on the inorganic photoelectric conversion device. In this case, electrodes are wired so that an organic photoelectric conversion device and an inorganic photoelectric conversion device are serially connected.

The inorganic photoelectric conversion device is fabricated by using an inorganic semiconductor. The inorganic semiconductor includes semiconductors made of a compound such as silicon, germanium, CIGS, CdTe, GaAs, and the like. Of them, silicon is preferable from the standpoint of production cost.

The organic photoelectric conversion device has an absorption edge at a wavelength shorter than that at which the inorganic photoelectric conversion device has. For this reason, the organic-inorganic hybrid photoelectric conversion device can utilize optical energy more effectively at a short wavelength and can obtain higher open end voltage than in the case of single use of an inorganic photoelectric conversion device. If high voltage is obtained, power loss due to wiring can be decreased.

The organic photoelectric conversion device is so formed as to permit at least partial permeation of light in a band absorbed by an inorganic photoelectric conversion device.

The organic photoelectric conversion device has a constitution containing first and second electrodes (positive electrode and negative electrode) and an active layer disposed between the electrodes.

The positive electrode and the negative electrode of the organic photoelectric conversion device are constituted of a transparent or semi-transparent electrode. Incident light from a transparent or semi-transparent electrode is absorbed in an electron-accepting compound and/or an electron-donating compound described later in an active layer, thereby generating an exciton obtained by binding an electron and a hole. When this exciton transfers in an active layer and reaches a heterojuction interface where an electron-accepting compound and an electron-donating compound are adjacent to each other, electrons and holes separate due to a difference in respective HOMO energy and LUMO energy at the interface and independently movable charges (electrons and holes) are generated. The generated charges transfer to respective electrodes, and taken out as electric energy (electric current) to the outside.

The organic photoelectric conversion device of the present invention is formed on an inorganic photoelectric conversion device. Alternatively, the organic photoelectric conversion device of the present invention is formed on a transparent supporting substrate which is then superimposed on an inorganic photoelectric conversion device. As the supporting substrate, those which do not chemically change in fabricating an organic photoelectric conversion device are suitably used. Examples of the supporting substrate include a glass substrate, a plastic substrate, a polymer film and the like. As the supporting substrate, substrates showing high light permeability are suitably used.

When the organic photoelectric conversion device is formed directly on an inorganic photoelectric conversion device, if the surface side of the inorganic photoelectric conversion device is formed of an n-type semiconductor, then, a positive electrode is formed on the side of the organic photoelectric conversion device to be brought into contact with the inorganic photoelectric conversion device, and if the surface side of the inorganic photoelectric conversion device is formed of a p-type semiconductor, then, a negative electrode is formed on the side of the organic photoelectric conversion device to be brought into contact with the inorganic photoelectric conversion device. When the organic photoelectric conversion device is formed directly on an inorganic photoelectric conversion device, the electrode facing the inorganic photoelectric conversion device, among the above-described first and second electrodes, can also be omitted.

### (Electrode of Organic Photoelectric Conversion Device)

As the electrode (positive electrode or negative electrode) of an organic photoelectric conversion device, use is made of an electrically conductive metal oxide film, a metal film, an electrically conductive film containing an organic substance, or the like. Specifically, films made of indium oxide, zinc oxide, tin oxide, indium tin oxide (Indium Tin Oxide: abbreviated as ITO), indium zinc oxide (Indium Zinc Oxide: abbreviated as IZO), gold, platinum, silver, copper, aluminum, polyaniline and its derivative, polythiophene and its derivative, and the like are used.

The application liquid used in forming an electrode by an application method contains a constituent material of the electrode and a solvent. It is preferable that the electrode contains a polymer compound showing electric conductivity, and it is preferable that the electrode is substantially composed of a polymer compound showing electric conductivity. The electrode constituent material includes organic materials such as polyaniline and its derivative, polythiophene and its derivative, polypyrrole and its derivative, and the like.

It is preferable that the electrode contains polythiophene and/or polythiophene derivative, and it is preferable that the electrode is substantially composed of polythiophene and/or polythiophene derivative. It is preferable that the negative electrode contains polyaniline and/or polyaniline derivative, and it is preferable that the negative electrode is composed of polyaniline and/or polyaniline derivative.

Specific examples of polythiophene and its derivative include compounds containing as a repeating unit one or more of a plurality of structural formulae shown below.

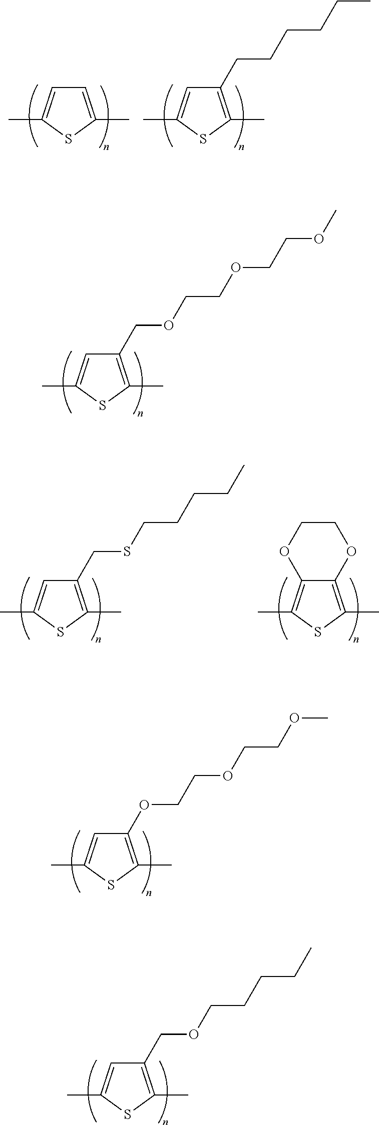

(wherein, n represents an integer of 1 or more.)

Specific examples of polypyrrole and its derivative include compounds containing as a repeating unit one or more of a plurality of structural formulae shown below.

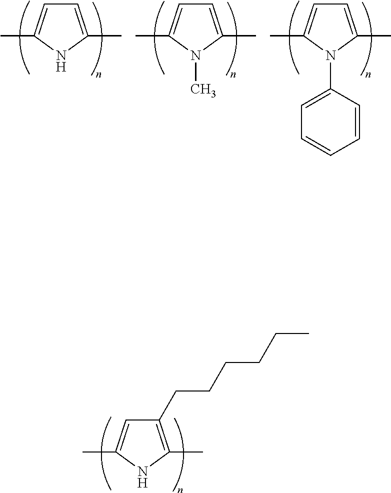

(wherein, n represents an integer of 1 or more.)

Specific examples of polyaniline and its derivative include compounds containing as a repeating unit one or more of a plurality of structural formulae shown below.

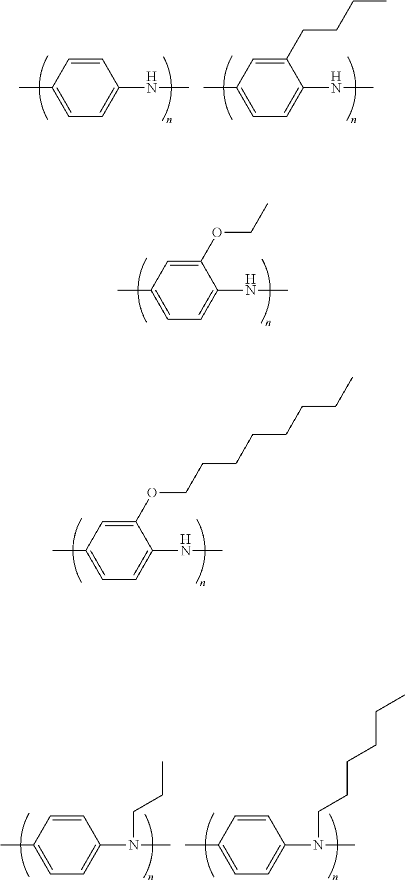

(wherein, n represents an integer of 1 or more.)

Of the above-described electrode constituent materials, PEDOT/PSS composed of poly(3,4-ethylenedioxythiophene) (PEDOT) and poly(4-styrenesulfonic acid) (PSS) is used suitably as the constituent material of an electrode since it shows high photoelectric conversion efficiency.

The material of an electrode is not limited to application liquid containing the above-described organic materials, and the electrode may also be formed by an application method using an emulsion or a suspension containing electrically conductive substance nanoparticles, electrically conductive substance nanowires or electrically conductive substance nanotubes, a dispersion such as a metal past and the like, a low melting point metal under melted condition, or the like. The electrically conductive substance includes metals such as gold, silver and the like, oxides such as ITO (indium tin oxide) and the like, carbon nanotubes and the like. Though the electrode may be constituted only of electrically conductive substance nanoparticles or nanofibers, the electrode may also have a constitution containing electrically conductive substance nanoparticles or nanofibers dispersed in a prescribed medium such as an electrically conductive polymer or the like, as described in Japanese Patent Application National Publication (Laid-Open) No. 2010-525526.

### (Active Layer of Organic Photoelectric Conversion Device)

The active layer of an organic photoelectric conversion device can take a single-layered form or a form of lamination of several layers. The single-layered active layer is constituted of a layer containing an electron-accepting compound and an electron-donating compound.

The active layer having a form of lamination of several layers is, for example, constituted of a laminate obtained by laminating a first active layer containing an electron-donating compound and a second active layer containing an electron-accepting compound. In this case, the first active layer is disposed closer to a positive electrode than the second active layer.

Further, a constitution of lamination of several active layers via an intermediate layer may also be permissible. In such as case, a multijunction device (tandem device) is obtained. In this case, each active layer may be a single layer containing an electron-accepting compound and an electron-donating compound, or may be a laminated layer constituted of a laminate obtained by laminating a first active layer containing an electron-donating compound and a second active layer containing an electron-accepting compound.

It is preferable that the active layer is formed by an application method. It is preferable that the active layer contains a polymer compound, and one polymer compound may be contained or two or more polymers may be contained in combination. It may also be permissible to mix an electron-donating compound and/or an electron-accepting compound into the above-described active layer, for enhancing the charge transportability of the active layer.

The electron-accepting compound used in an organic photoelectric conversion device is composed of a compound having the HOMO energy higher than the HOMO energy of an electron-donating compound and having the LUMO energy higher than the LUMO energy of an electron-donating compound.

The above-described electron-donating compound may be a low molecular weight compound or a high molecular weight compound. The low molecular weight electron-donating compound includes phthalocyanine, metallophthalocyanine, porphyrin, metalloporphyrin, oligothiophene, tetracene, pentacene, rubrene and the like.

The high molecular weight electron-donating compound includes polyvinylcarbazole and derivatives thereof, polysilane and derivatives thereof, polysiloxane derivatives having an aromatic amine in the side chain or main chain, polyaniline and derivatives thereof, polythiophene and derivatives thereof, polypyrrole and derivatives thereof, polyphenylenevinylene and derivatives thereof, polythienylenevinylene and derivatives thereof, polyfluorene and derivatives thereof, and the like.

The above-described electron-accepting compound may be a low molecular weight compound or a high molecular weight compound.

The low molecular weight electron-accepting compound includes oxadiazole derivatives, anthraquinodimethane and derivatives thereof, benzoquinone and derivatives thereof, naphthoquinone and derivatives thereof, anthraquinone and derivatives thereof, tetracyanoanthraquinodimethane and derivatives thereof, fluorenone derivatives, diphenyldicyanoethylene and derivatives thereof, diphenoquinone derivatives, metal complexes of 8-hydroxyquinoline and derivatives thereof, polyquinoline and derivatives thereof, polyquinoxaline and derivatives thereof, polyfluorene and derivatives thereof, fullerenes such as C₆₀ and the like and derivatives thereof, phenanthrene derivatives such as bathocuproine and the like; etc.

The high molecular weight electron-accepting compound includes polyvinylcarbazole and derivatives thereof, polysilane and derivatives thereof, polysiloxane derivatives having an aromatic amine in the side chain or main chain, polyaniline and derivatives thereof, polythiophene and derivatives thereof, polypyrrole and derivatives thereof, polyphenylenevinylene and derivatives thereof, polythienylenevinylene and derivatives thereof, polyfluorene and derivatives thereof, and the like.

Of them, fullerenes and derivatives thereof are especially preferable.

The fullerenes include C₆₀, C₇₀, carbon nanotubes and derivatives thereof. Specific structures of derivatives of C₆₀ fullerene include those described below.

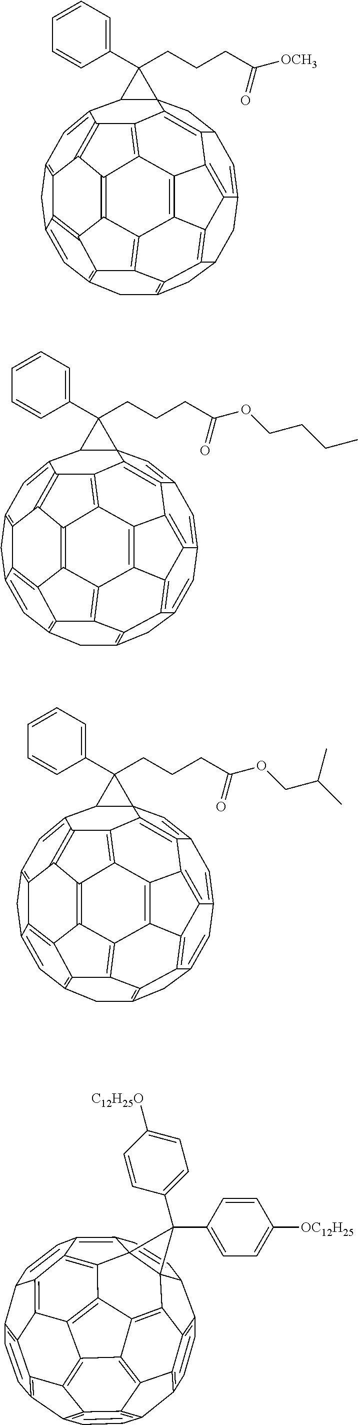

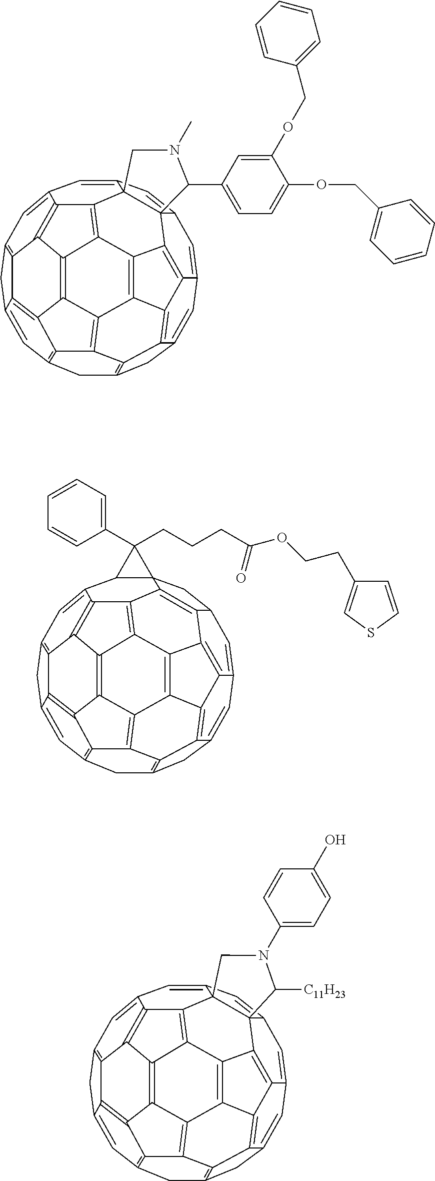

When the active layer contains an electron-accepting compound composed of a fullerene and/or a fullerene derivative and an electron-donating compound, the proportion of the fullerene and the fullerene derivative is preferably 10 to 1000 parts by weight, more preferably 50 to 500 parts by weight with respect to 100 parts by weight of the electron-donating compound. The organic photoelectric conversion device preferably has a single-layered active layer described above, and more preferably has a single-layered active layer containing an electron-accepting compound composed of a fullerene and/or a fullerene derivative and an electron-donating compound from the standpoint of much inclusion of heterojunction interfaces.

Especially, it is preferable for the active layer to contain a conjugated polymer compound and a fullerene and/or a fullerene derivative. The conjugated polymer compound used in the active layer includes polythiophene and derivatives thereof, polyphenylenevinylene and derivatives thereof, polyfluorene and derivatives thereof, and the like.

The thickness of the active layer is usually 1 nm to 100 μm, preferably 2 nm to 1000 nm, more preferably 5 nm to 500 nm, further preferably 20 nm to 200 nm.

### (Functional Layer of Organic Photoelectric Conversion Device)

The organic photoelectric conversion device sometimes has a prescribed functional layer between electrodes in addition to an active layer. As the functional layer, a functional layer containing an electron transporting material is preferably disposed between an active layer and a negative layer.

The functional layer is preferably formed by an application method, and it is preferable, for example, to form a functional layer by applying application liquid containing an electron transporting material and a solvent on the surface of a layer on which the functional layer is to be provided. In the present invention, the application liquid includes also dispersions such as an emulsion, a suspension and the like.

The electron transporting material includes, for example, zinc oxide, titanium oxide, zirconium oxide, tin oxide, indium oxide, ITO (indium tin oxide), FTO (fluorine-doped tin oxide), GZO (gallium-doped zinc oxide), ATO (antimony-doped tin oxide) and AZO (aluminum-doped zinc oxide), and of them, zinc oxide is preferable. In forming a functional layer, it is preferable to subject application liquid containing granular zinc oxide to film formation, thereby forming the functional layer. As the electron transporting material, so-called zinc oxide nanoparticles are preferably used, and it is more preferable to form a functional layer using an electron transporting material composed only of zinc oxide nanoparticles. Zinc oxide has a sphere-equivalent average particle size of preferably 1 nm to 1000 nm, more preferably 10 nm to 100 nm. The average particle size is measured by a laser diffraction scattering method, an X-ray diffraction method or a laser Doppler method

### (Dynamic Electrophoretic Light Scattering Method).

A functional layer containing an electron transporting material can be provided between a negative electrode and an active layer, to prevent peeing of the negative electrode and to enhance efficiency of electron injection from the active layer into the negative electrode. It is preferable that a functional layer is provided in contact with an active layer, and it is further preferable that a functional layer is provided also in contact with a negative electrode. By thus providing a functional layer containing an electron transporting material, peeling of a negative electrode can be prevented and efficiency of electron injection from an active layer into a negative electrode can be further enhanced. By providing such a functional layer, an organic photoelectric conversion device showing high reliability and giving high photoelectric conversion efficiency can be realized.

The functional layer containing an electron transporting material functions as what is called an electron transporting layer and/or an electron injection layer. By providing such a functional layer, efficiency of injection of electrons into a negative electrode can be enhanced, injection of holes from an active layer can be prevented, an electron transporting ability can be enhanced, an active layer can be protected from erosion by application liquid used in forming a negative electrode by an application method, and deterioration of an active layer can be suppressed.

The functional layer containing an electron transporting material is preferably constituted of a material showing high wettability for application liquid used in forming a negative electrode by application. Specifically, it is preferable that the functional layer containing an electron transporting material shows higher wettability for application liquid than wettability of an active layer for application liquid used in forming a negative electrode by application. By forming a negative electrode on such a functional layer by application, application liquid wets and spreads successfully on the surface of the functional layer in forming the negative electrode, thus, a negative electrode having uniform thickness can be formed.

The constitution of an organic photoelectric conversion device is not limited to the above-described device constitution, and an additional layer may be further provided between a positive electrode and a negative electrode. The additional layer includes, for example, a hole transporting layer which transports holes, an electron transporting layer which transports electrons, a buffer layer and the like. For example, a hole transporting layer is provided between a positive electrode and an active layer, an electron transporting layer is provided between an active layer and a functional layer, a buffer layer is provided, for example, between a negative electrode and a functional layer, or the like. By providing a buffer layer, flattening of the surface and charge injection can be promoted.

As the material used in a hole transporting layer or an electron transporting layer as the above-described additional layer, the electron-donating compound or the electron-accepting compound described above can be used respectively. As the material used in a buffer layer as the additional layer, use can be made of halides, oxides and the like of alkali metals and alkaline earth metals such as lithium fluoride and the like. It is also possible to form a charge transporting layer by using fine particles of an inorganic semiconductor such as titanium oxide and the like. For example, an electron transporting layer can be formed by forming a film with a titania solution by an application method on a ground layer on which the electron transporting layer is to be formed and by further drying it.

### <2> Method of Producing Organic-Inorganic Hybrid Photoelectric Conversion Device

The method for producing an organic-inorganic hybrid photoelectric conversion device of the present invention relates to a method for producing an organic-inorganic hybrid photoelectric conversion device comprising a step of preparing an inorganic photoelectric conversion device and a step of forming an organic photoelectric conversion device on the inorganic photoelectric conversion device, wherein in the step of forming the organic photoelectric conversion device, an active layer is formed by an application method on the inorganic photoelectric conversion device.

### < First Electrode Forming Step>

After preparing an inorganic photoelectric conversion device, a first electrode is formed first. When an organic photoelectric conversion device is formed directly on an inorganic photoelectric conversion device as described above, it is also possible to omit the first electrode forming step.

The electrode is formed by forming a film with the electrode material exemplified above on the supporting substrate described above by a vacuum vapor deposition method, a sputtering method, an ion plating method, a plating method or the like. The electrode may also be formed by an application method using application liquid containing an organic material such as polyaniline and its derivative, polythiophene and its derivative and the like, a metal ink, a metal paste, a low melting point metal under melted condition, and the like.

The solvent in application liquid used in forming an electrode by application includes, for example, hydrocarbon solvents such as toluene, xylene, mesitylene, tetralin, decalin, bicyclohexyl, n-butylbenzene, s-butylbenzene, t-butylbenzene and the like, halogenated saturated hydrocarbon solvents such as carbon tetrachloride, chloroform, dichloromethane, dichloroethane, chlorobutane, bromobutane, chloropentane, bromopentane, chlorohexane, bromohexane, chlorocyclohexane, bromocyclohexane and the like, halogenated unsaturated hydrocarbon solvents such as chlorobenzene, dichlorobenzene, trichlorobenzene and the like, ether solvents such as tetrahydrofuran, tetrahydropyran and the like, water, alcohols, and the like. Specific examples of the alcohol include methanol, ethanol, isopropanol, butanol, ethylene glycol, propylene glycol, butoxyethanol, methoxybutanol and the like. The application liquid used in the present invention may contain two or more solvents, and two or more of the solvents exemplified above may be contained.

In the case of formation of an electrode using application liquid which imparts damages on an active layer and a functional layer, it may be permissible, for example, that an electrode is endowed with a two-layer constitution in which a first film is formed by using application liquid which does not impart damages on an active layer and a functional layer, then, a second film is formed by using application liquid which possibly imparts damages on an active layer and a functional layer. By fabricating an electrode having a two-layer constitution as described above, it is possible to suppress damages on an active layer and a functional layer since the first film functions as a protective layer even if the second film is formed using application liquid which possibly imparts damages on an active layer and a functional layer. For example, if an electrode is formed on a functional layer composed of zinc oxide, an electrode having a two-layer constitution may be formed by forming a first film using neutral application liquid, and subsequently forming a second film using an acidic solution, since the functional layer composed of zinc oxide is easily damaged by an acidic solution.

### < Active Layer Forming Step>

Though the method of forming an active layer is not particularly restricted, it is preferable to form an active layer by an application method from the standpoint of simplification of the production step. The active layer can be formed by an application method using application liquid containing, for example, the above-described active layer constituent material and a solvent, and can be formed by an application method using application liquid containing, for example, a conjugated polymer compound and a fullerene and/or a fullerene derivative and a solvent.

The solvent includes, for example, hydrocarbon solvents such as toluene, xylene, mesitylene, tetralin, decalin, bicyclohexyl, n-butylbenzene, s-butylbenzene, t-butylbenzene and the like, halogenated saturated hydrocarbon solvents such as carbon tetrachloride, chloroform, dichloromethane, dichloroethane, chlorobutane, bromobutane, chloropentane, bromopentane, chlorohexane, bromohexane, chlorocyclohexane, bromocyclohexane and the like, halogenated unsaturated hydrocarbon solvents such as chlorobenzene, dichlorobenzene, trichlorobenzene and the like, ether solvents such as tetrahydrofuran, tetrahydropyran and the like; etc.

The application liquid used in the present invention may contain two or more solvents, and two or more of the solvents exemplified above may be contained.

The method of applying application liquid containing the above-described active layer constituent material includes application methods such as a spin coat method, a casting method, a micro gravure coat method, a gravure coat method, a bar coat method, a roll coat method, a wire bar coat method, a dip coat method, a spray coat method, a screen printing method, a flexo printing method, an offset printing method, an ink jet printing method, a dispenser printing method, a nozzle coat method, a capillary coat method and the like, and of them, a spin coat method, a flexo printing method, an ink jet printing method and a dispenser printing method are preferable.

### < Functional Layer Forming Step>

It is preferable to form a functional layer containing an electron transporting material between an active layer and a negative electrode, as described above. That is, it is preferable to form a functional lay by applying application liquid containing the above-described electron transporting material on an active layer to form a film, after formation of the above-described active layer and before formation of the above-described negative electrode.

When a functional layer containing an electron transporting material is provided in contact with an active layer, the functional layer is formed by applying the above-described application liquid on the surface of the active layer. In forming a functional layer, it is preferable to use application liquid imparting little damages on layers (active layer and the like) on which the application liquid is to be applied, and specifically, it is preferable to use application liquid which scarcely dissolves layers (active layer and the like) on which the application liquid is to be applied. For example, when application liquid used in forming a film of a negative electrode is applied on an active layer, it is preferable to form a functional layer by using application liquid imparting smaller damages on an active layer than the damages imparted on an active layer by the above-described application liquid, and specifically, it is preferable to form a functional layer by using application liquid which more scarcely dissolves an active layer than the application liquid used in forming a film of a negative electrode.

The application liquid used in forming a functional layer by application contains a solvent and the above-described electron transporting material. The solvent in the above-described application liquid includes water, alcohols and the like, and specific examples of the alcohol include methanol, ethanol, isopropanol, butanol, ethylene glycol, propylene glycol, butoxyethanol, methoxybutanol and the like. The application liquid used in the present invention may contain two or more solvents, and two or more of the solvents exemplified above may be contained.

### < Second Electrode Forming Step>

After forming an active layer and a functional layer, an electrode is further formed. In this second electrode forming step, an electrode can be formed by the same manner as explained in the section of the first electrode forming step. In the second electrode forming step, it is preferable for form an electrode of an organic photoelectric conversion device by an application method.

### EXAMPLES

Examples will be shown below for illustrating the present invention further in detail, but the present invention is not limited to these examples.

In the following examples, polystyrene-equivalent number-average molecular weight was measured as the molecular weight of a polymer by using GPC manufactured by GPC Laboratory (PL-GPC2000). A polymer was dissolved in o-dichlorobenzene so that the concentration of the polymer was about 1 wt %. As the mobile phase of GPC, o-dichlorobenzene was used and allowed to flow at a flow rate of 1 mL/min at a measurement temperature of 140° C. As the column, three columns of PLGEL 10 μm MIXED-B (manufactured by PL Laboratory) were connected in series.

### Synthesis Example 1

### Synthesis of Polymer 1

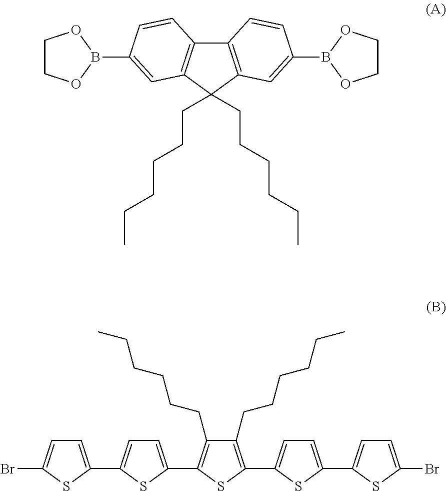 [SMILES: CCCCCCC1(CCCCCC)c2cc(B3OCCO3)ccc2-c2ccc(B3OCCO3)cc21 ; CCCCCCc1c(-c2ccc(-c3ccc(Br)s3)s2)sc(-c2ccc(-c3ccc(Br)s3)s2)c1CCCCCC]

Into a 2 L four-necked flask of which internal gas had been purged with argon were charged the above-described compound A (7.928 g, 16.72 mmol), the above-described compound B (13.00 g, 17.60 mmol), methyltrioctylammonium chloride (trade name: aliquat336, manufactured by Aldrich, CH₃N[(CH₂)₇CH₃]₃Cl, density 0.884 g/ml, 25° C., trademark of Henkel Corporation) (4.979 g) and 405 ml of toluene, and argon was bubbled through the system while stirring for 30 minutes.

Dichlorobis(triphenylphosphine)palladium(II) (0.02 g) was added, and the mixture was heated up to 105° C., and 42.2 ml of a 2 mol/L sodium carbonate aqueous solution was dropped while stirring. After completion of dropping, they were reacted for 5 hours, and phenylboronic acid (2.6 g) and 1.8 ml of toluene were added and the mixture was stirred at 105° C. for 16 hours. Toluene (700 ml) and 200 ml of a 7.5% sodium diethyldithiocarbamate trihydrate aqueous solution were added and the mixture was stirred at 85° C. for 3 hours. After removal of the aqueous layer, the residual portion was washed with 300 ml of ion-exchanged water of 60° C. twice, with 300 ml of 3% acetic acid of 60° C. once, further, with 300 ml of ion-exchanged water of 60° C. three times. The organic layer was allowed to pass through a column filled with Celite, alumina and silica, and the column was washed with 80 ml of hot toluene. The solution was concentrated to 700 ml, then, poured into 2 L of methanol, to cause re-precipitation. The polymer was recovered by filtration, and washed with 500 ml of methanol, acetone and methanol. The product was dried in vacuum overnight at 50° C. to obtain 12.21 g of a pentathienyl-fluorene copolymer (hereinafter, referred to as “polymer 1”) having a repeating unit represented by the following formula:

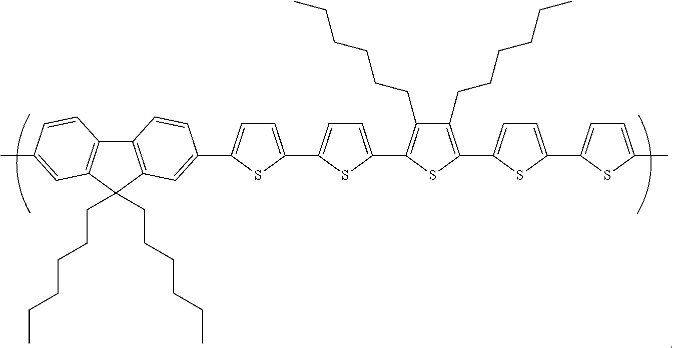

The polymer 1 had a polystyrene-equivalent number-average molecular weight of 5.4×10⁴ and a polystyrene-equivalent weight-average molecular weight of 1.1×10⁵.

### Synthesis Example 2

### Synthesis of Polymer 2

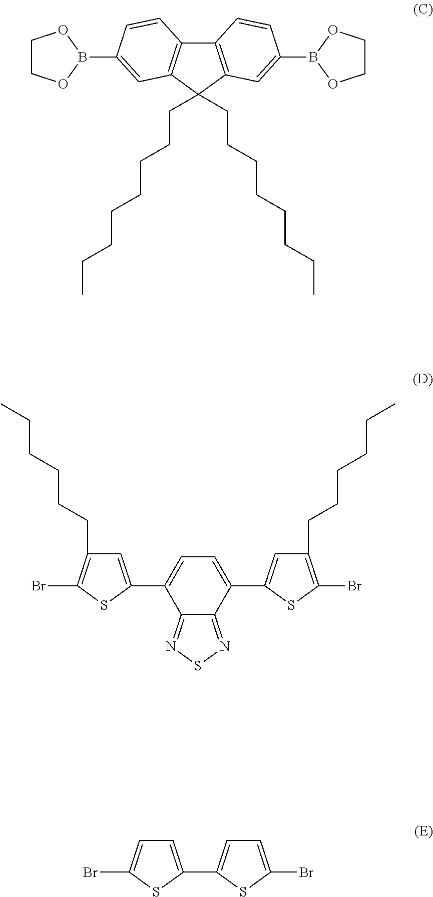 [SMILES: CCCCCCCCC1(CCCCCCCC)c2cc(B3OCCO3)ccc2-c2ccc(B3OCCO3)cc21 ; CCCCCCc1cc(-c2ccc(-c3cc(CCCCCC)c(Br)s3)c3nsnc23)sc1Br ; Brc1ccc(-c2ccc(Br)s2)s1]

Into a 200 ml separable flask were charged 0.65 g of methyltrioctylammonium chloride (trade name: aliquat 336 (registered trademark), manufactured by Aldrich, CH₃N[(CH₂)₇CH₃]₃Cl, density 0.884 g/ml, 25° C.), 1.5779 g of the compound (C) and 1.1454 g of the compound (E), and a gas in the flask was purged with nitrogen. Into the flask was added 35 ml of toluene bubbled with argon, the mixture was stirred to cause dissolution, then, argon was further bubbled through the mixture for 40 minutes. The temperature of a bath for heating the flask was raised up to 85° C., then, 1.6 mg of palladium acetate and 6.7 mg of tris o-methoxyphenylphosphine were added to the reaction liquid, subsequently, 9.5 ml of a 17.5 wt % sodium carbonate aqueous solution was dropped over a period of 6 minutes while raising the temperature of the bath up to 105° C. After dropping, the mixture was stirred for 1.7 hours while keeping the temperature of the bath at 105° C., thereafter, the reaction liquid was cooled down to room temperature.

Next, 1.0877 g of the compound (C) and 0.9399 g of the compound (D) were added to the reaction liquid, and further, 15 ml of toluene bubbled with argon was added, and the mixture was stirred to cause dissolution, then, the mixture was further bubbled with argon for 30 minutes. To the reaction liquid were added 1.3 mg of palladium acetate and 4.7 mg of tris o-methoxyphenylphosphine, subsequently, 6.8 ml of a 17.5 wt % sodium carbonate aqueous solution was dropped over a period of 5 minutes while raising the temperature of the bath up to 105° C. After dropping, the mixture was stirred for 3 hours while keeping the temperature of the bath at 105° C. After dropping, to the reaction liquid were added 50 ml of toluene bubbled with argon, 2.3 mg of palladium acetate, 8.8 mg of tris o-methoxyphenylphosphine and 0.305 g of phenylboric acid, and the mixture was stirred for 8 hours while keeping the temperature of the bath at 105° C. Next, the aqueous layer of the reaction liquid was removed, then, an aqueous solution prepared by dissolving 3.1 g of sodium N,N-diethyldithiocarbamate in 30 ml of water was added, and the mixture was stirred for 2 hours while keeping the temperature of the bath at 85° C. Subsequently, 250 ml of toluene was added to the reaction liquid to cause separation of the reaction liquid, and the organic layer was washed with 65 ml of water twice, 65 ml of 3 wt % acetic acid water twice, and 65 ml of water twice. To the organic layer after washing was added 150 ml of toluene for dilution, and the diluted solution was dropped into 2500 ml of methanol, to cause re-precipitation of a polymer compound. The polymer compound was filtrated, and dried under reduced pressure, then, dissolved in 500 ml of toluene. The resultant toluene solution was allowed to pass through a silica gel-alumina column, and the resultant toluene solution was dropped into 3000 ml of methanol, to cause re-precipitation of a polymer compound. The polymer compound was filtrated, and dried under reduced pressure, then, 3.00 g of a polymer 2 was obtained. The resultant polymer 2 had a polystyrene-equivalent weight-average molecular weight of 257000 and a polystyrene-equivalent number-average molecular weight of 87000.

The polymer 2 is a block copolymer represented by the following formula.

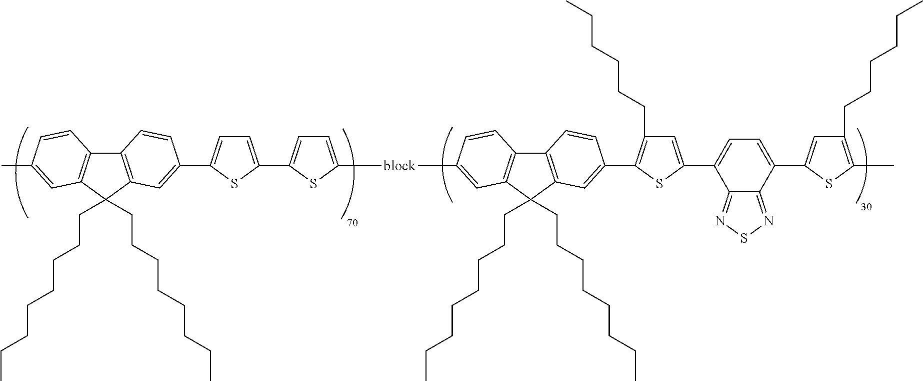

### (Production of Composition 1)

Twenty five (25) parts by weight of [6,6]-phenyl C71-butyric acid methyl ester (C70PCBM) (ADS71BFA manufactured by American Dye Source, Inc.) as a fullerene derivative, 2.5 parts by weight of the polymer 1 and 2.5 parts by weight of the polymer 2 as an electron donor compound, and 1000 parts by weight of o-dichlorobenzene as a solvent were mixed. Next, the mixed solution was filtrated through a Teflon (registered trademark) filter having a pore size of 1.0 μm, to prepare a composition 1.

### Measurement Example 1

### Fabrication and Evaluation of Organic Photoelectric Conversion Device

A glass substrate on which an ITO film functioning as a positive electrode of a solar battery had been formed was prepared. The ITO film had been formed by a sputtering method, and its thickness was 150 nm. This glass substrate was treated with ozone and UV, performing surface treatment of the ITO film. Next, a PEDOT:PSS solution (manufactured by H. C. Starck; CleviosP VP AI4083) was applied on the ITO film by spin coating, and heated in atmospheric air at 120° C. for 10 minutes, to form a hole injection layer having a thickness of 50 nm. On this hole injection layer, the above-described composition 1 was applied by spin coating, to form an active layer (thickness: about 230 nm).

Next, a 20 wt % methyl ethyl ketone dispersion of gallium-doped zinc oxide nanoparticles (Paget GK, manufactured by Hakusuitech Co. Ltd.) was applied with a thickness of 220 nm on the active layer by spin coating, to form a functional layer insoluble in water solvent.

Next, a wire-formed conductor dispersion in water solvent (ClearOhm (registered trademark) Ink-N AQ: manufactured by Cambrios Technologies Corporation) was applied by a spin coater and dried, to obtain a negative electrode composed of an electrically conductive wire layer having a thickness of 120 nm. Thereafter, sealing was performed with an UV-curable sealant, to obtain a semi-transparent organic photoelectric conversion device.

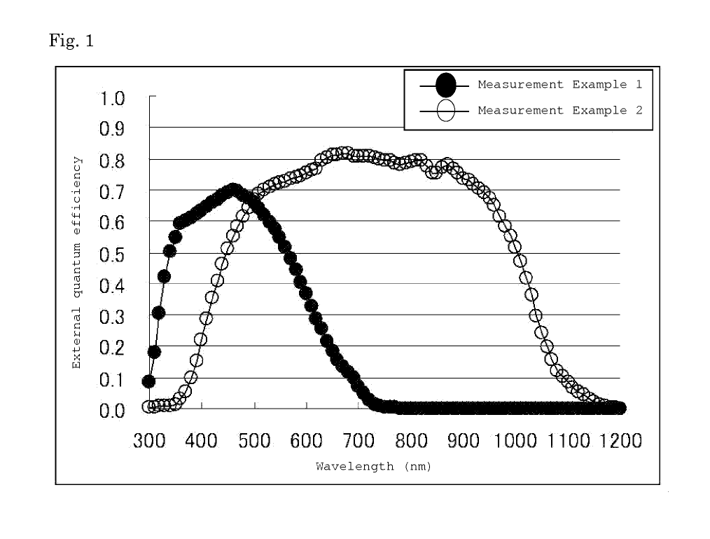

The resultant organic photoelectric conversion device had a shape of 1.8 mm×1.8 mm regular tetragon. The resultant organic photoelectric conversion device was irradiated with constant light using a solar simulator (manufactured by Bunkoukeiki Co., Ltd., trade name OTENTO-SUNII: AM1.5G filter, irradiance 100 mW/cm²), and the generating current and voltage were measured, to know photoelectric conversion efficiency. The photoelectric conversion efficiency was 5.43%, the short-circuit current density was 9.76 mA/cm², the open end voltage was 0.80V, and FF (fill factor) was 0.69. The spectral sensitivity measured by a spectral sensitivity measuring apparatus (manufactured by Bunkoukeiki Co., Ltd.; CEP-2000) is shown in FIG. 1. The absorption edge of the organic photoelectric conversion device judged from FIG. 1 is 730 nm.

### Measurement Example 2

### Evaluation of Inorganic Photoelectric Conversion Device

A silicon-based photodiode detector (manufactured by Bunkoukeiki Co., Ltd.; BS-500) was irradiated with constant light using a solar simulator (manufactured by Bunkoukeiki Co., Ltd., trade name OTENTO-SUNII: AM1.5G filter, irradiance 100 mW/cm²) and the generating current and voltage were measured, to know photoelectric conversion efficiency. The photoelectric conversion efficiency was 9.12%, the short-circuit current density was 30.67 mA/cm², the open end voltage was 0.576V, and FF was 0.52. The spectral sensitivity measured by a spectral sensitivity measuring apparatus (manufactured by Bunkoukeiki Co., Ltd. CEP-2000) is shown in FIG. 1. The absorption edge of the inorganic photoelectric conversion device judged from FIG. 1 is 1180 nm.

As shown by the spectral sensitivity, the organic photoelectric conversion device shows spectral sensitivity at a short wavelength since the organic photoelectric conversion device shows an absorption edge at a shorter wavelength than that of the photodiode detector.

### Example 1

### Evaluation of Organic-Inorganic Hybrid Photoelectric Conversion Device

On a silicon-based photodiode detector (manufactured by Bunkoukeiki Co., Ltd.; BS-500), the semi-transparent organic photoelectric conversion device used in Measurement Example 1 was superimposed, and a negative electrode of the photodiode detector and a positive electrode of the organic film solar battery were wired, to fabricate a serially-connected tandem type organic-inorganic hybrid photoelectric conversion device. Irradiation with constant light was performed using a solar simulator (manufactured by Bunkoukeiki Co., Ltd., trade name OTENTO-SUNII:AM1.5G filter, irradiance 100 mW/cm²) and current and voltage generating between a positive electrode of the photodiode detector and a negative electrode of the organic film solar battery were measured, to know photoelectric conversion efficiency. The photoelectric conversion efficiency was 9.35%, the short-circuit current density was 9.85 mA/cm², the open end voltage was 1.34V, and FF was 0.71.

As shown in Example 1, the organic-inorganic hybrid photoelectric conversion device exhibited high open end voltage and photoelectric conversion efficiency.

### INDUSTRIAL APPLICABILITY

According to the present invention, an organic-inorganic hybrid photoelectric conversion device having high open end voltage can be provided, and if an organic photoelectric conversion device is fabricated by an application method, production cost can be reduced.

1. An organic-inorganic hybrid photoelectric conversion device comprising:
an inorganic photoelectric conversion device comprising an inorganic semiconductor; and
an organic photoelectric conversion device which is connected in series to the inorganic photoelectric conversion device and is superimposed on the inorganic photoelectric conversion device,
wherein the organic photoelectric conversion device comprises an active layer comprising an electron-accepting compound and an electron-donating compound and has an absorption edge at a wavelength shorter than that at which the inorganic photoelectric conversion device has.

2. The organic-inorganic hybrid photoelectric conversion device according to claim 1, wherein the active layer of the organic photoelectric conversion device has been formed by an application method.

3. The organic-inorganic hybrid photoelectric conversion device according to claim 1, wherein an electrode of the organic photoelectric conversion device has been formed by an application method.

4. The organic-inorganic hybrid photoelectric conversion device according to claim 1, wherein the active layer of the organic photoelectric conversion device comprises a fullerene and/or a fullerene derivative and a conjugated polymer compound.

5. The organic-inorganic hybrid photoelectric conversion device according to claim 1, wherein the inorganic semiconductor used in the inorganic photoelectric conversion device is silicon.

6. A method for producing an organic-inorganic hybrid photoelectric conversion device comprising:
a step of preparing an inorganic photoelectric conversion device; and
a step of forming an organic photoelectric conversion device on the inorganic photoelectric conversion device, wherein in the step of forming the organic photoelectric conversion device, an active layer of the organic photoelectric conversion device is formed by an application method on the inorganic photoelectric conversion device.

7. The method for producing an organic-inorganic hybrid photoelectric conversion device according to claim 6, wherein in the step of forming the organic photoelectric conversion device, an electrode of the organic photoelectric conversion device is formed by an application method after the formation of the active layer.
